(19) United States
(12) Patent Application Publication
(10) Pub. No.: US 2011/0194036 A1
(43) Pub. Date: Aug. 11, 2011

(54) PHOTODIODE, PHOTODIODE-EQUIPPED DISPLAY DEVICE, AND FABRICATION METHOD THEREFOR

(75) Inventors: Nami Okajima, Osaka (JP); Masahiro Fujiwara, Osaka (JP)

(73) Assignee: SHARP KABUSHIKI KAISHA, Osaka (JP)

(21) Appl. No.: 13/122,730

(22) PCT Filed: Jun. 9, 2009
(86) PCT No.: PCT/JP2009/060550

§ 371 Date: Apr. 5, 2011

(30) Foreign Application Priority Data
Oct. 9, 2008 (JP) 2008-262746

(51) Int. Cl. G02F 1/13; H01L 29/04; H01L 33/08

(52) U.S. Cl. 349/1; 257/59; 257/72; 438/34; 257/E29.003; 257/E33.005

(57) ABSTRACT

A photodiode (10) of the present invention has a p-type semiconductor region (11), an i-type semiconductor region (12), and an n-type semiconductor region (13). The channel length “L” of the photodiode (10) is determined by the source wiring films (8) formed by etching. This configuration provides a display device equipped with the plurality of photodiodes (10) having consistent properties.

### TECHNICAL FIELD

The present invention relates to a photodiode, a photodiode-equipped display device and a fabrication method for the same. More particularly, the present invention relates to a photodiode preferably used for a liquid crystal display device having a plurality of active elements and driven by the active elements, a display device equipped with the photodiode, a method for fabricating the photodiode, and a method of making a display device equipped with the photodiode.

### BACKGROUND ART

Liquid crystal display devices are used in a wide variety of equipment. Devices utilizing photodiodes are increasingly diversified, and so is the environment in which the liquid crystal display devices are used. Superior operability under versatile environment as well as energy-saving features are strongly in demand. Liquid crystal display devices themselves offer an increasing range of functions nowadays, expanding their application field.

An example of a multi-functional liquid crystal display device as disclosed in Patent Document 1 can capture images. The display device disclosed in Patent Document 1 is a display device having, on the image element array substrate constituting a liquid crystal display device, an optical sensor that can capture images.

Display devices having the image-capturing capability directly incorporate, on the image element array substrate constituting a liquid crystal display device, an optical sensor that can capture images. The charge of a capacitor connected to the optical sensor is designed to change according to the amount of light received by the optical sensor. Images are captured by detecting the voltages across the capacitor.

This optical sensor is composed of, for example, a photodiode. In the formation process of active elements such as TFTs for driving pixels of a display device, the photodiode can be formed at the same time. The photodiode therefore can be disposed with ease in each individual pixel.

In liquid crystal display devices, the display quality depends heavily on the operation environment, in particular, the ambient brightness (external light) of the site where the display is used. The display luminance is therefore adjusted according to the ambient brightness. For ambient brightness detection, optical sensors are employed in display devices. In the case of liquid crystal display devices, photodiodes as optical sensors are readily formed on the active element substrate together with active elements such as TFTs in the same formation process.

FIG. 4 shows an example of a liquid crystal display device equipped with optical sensors. In FIG. 4, “40” denotes a liquid crystal panel that has a substrate 41 having a plurality of active elements such as TFTs thereon, and an opposite substrate 42. On the substrate 41, a plurality of pixel electrodes formed of transparent conductive film, and a plurality of active elements for driving the pixel electrodes, such as thin film transistors (TFTs), are disposed. A plurality of pixel electrodes and the like are disposed in a matrix to form a display region. On the opposite substrate 42, opposite electrodes and color filters (both not shown in FIG. 4) are disposed. The opposite substrate 42 is disposed to be opposed to the display region of the substrate 41.

On the substrate 41, data drivers 43 and gate drivers 44 are formed in the area peripheral to the display region. The active elements disposed on the display region are connected to the data drivers or the gate drivers via data lines or gate lines (both not shown), respectively. Furthermore, a plurality of photodiodes 45 are disposed in the area peripheral to the display region of the substrate 41.

FIG. 5 and FIG. 6 illustrate a photodiode as an optical sensor used for a display device such as described above. The photodiode technology shown in FIG. 6 is disclosed in Japanese Patent Application No. 2007-115913, filed by the same applicants as those of the present invention, as a prior application filed on Apr. 25, 2007.

In FIGS. 5 and 6, the same reference characters are used for identical members. In FIGS. 5 and 6, “60” denotes a photodiode as an optical sensor, which is a lateral photodiode composed of a p-type semiconductor region 61, an i-type semiconductor region 62, and an n-type semiconductor region 63. The photodiode 60 is made of a silicon film formed on a base coat insulating film 53 disposed over a substrate 51 that is made of a material such as glass. This silicon film is formed simultaneously with the silicon film for making elements such as TFTs on the display region.

The p-type semiconductor region 61 and n-type semiconductor region 63 of the photodiode 60 are connected to source wiring films 58 through wirings 57 provided in the contact holes disposed through a gate insulating film 54, interlayer insulating film 55 and planarizing layer 56. This configuration makes the source wiring films 58 the external lead-out terminals. “59” denotes a protective film. “52” is a light shielding film made of a metal or the like, which is employed to shield light from the bottom in FIGS. 5 and 6.

The gate insulating film 54 is a layer that insulates the gate electrode of the TFT formed simultaneously with the photodiode 60. In FIG. 5, the electrode film constituting the gate electrode has been removed, and therefore not shown in FIG. 5. In FIG. 6, a metal or other conductive film that is going to be the gate electrode in the TFT formation region is left as metal wirings 67 and 68 in the photodiode 60 formation region. The role of the metal wirings 67 and 68 will be described in detail later.

Similarly, source wiring film 58 is formed of a metal or other conductive film utilized as source wiring in TFT fabricated simultaneously with the photodiode 60. The source wiring film 58 is so named due to this fabrication process. FIG. 5 shows a case in which a photodiode is formed in the display region of the liquid crystal display device. In the figure, “65” and “66” denote a liquid crystal layer and an opposite substrate, respectively. In this case, the photodiode may be formed for each pixel.

The output properties of the photodiode 60 shown in FIG. 5 are determined by the length of the i-type semiconductor region 62 (i layer) in the forward direction, i.e., the channel length. Irregular channel length causes irregular output properties. The precision of the i-type semiconductor region 62 heavily depends on the alignment precision of the resist pattern, a mask used in the ion implantation. The alignment precision of the resist pattern, however, is not necessarily high, and as a result, the output properties of individual photodiodes are variable. This is an issue to be solved.

The photodiode shown in FIG. 6 was devised in consideration of the issues of the photodiode shown in FIG. 5, and is designed to minimize the variation in channel length of the photodiode 60 by using metal wirings 67 and 68, which are the metal films formed in the gate electrode formation process.

In FIG. 6, the metal wirings 67 and 68 are formed in the same formation process as the gate electrode for the TFT in the display region. The metal wirings 67 and 68 are formed by etching. The alignment precision achieved in this manner is higher than the alignment precision of the mask formed by a resist pattern alone. The metal wirings 67 and 68 are used to form a mask for implanting impurities, to implant p-type and n-type ion impurities, and to form the p-type semiconductor region 61 and the n-type semiconductor region 63. The ion implantation creates a region where neither p-type impurities nor n-type impurities are implanted, which is the i-type semiconductor region 62.

The precision of the i-type semiconductor region 62 formed in this manner depends on the etching precision for the metal wirings 67 and 68. The channel length, therefore, depends on the formation precision of the metal wirings 67 and 68. As described above, the etching precision of the metal wirings 67 and 68 is higher than the resist pattern alignment precision. Etching therefore provides a higher precision in the channel length.

### RELATED ART DOCUMENTS

### Patent Documents

Patent Document 1: Japanese Patent Application Laid-Open Publication No. 2006-3587 Publication date: Jan. 5, 2006)

### SUMMARY OF THE INVENTION

A high precision of channel length of a photodiode can be achieved according to the technology disclosed in FIG. 6 described above. However, in this method, the metal wirings 67 and 68, which were conventionally not formed, are formed over the i-type semiconductor region 62. As a result, the aperture ratio of the display is lowered. Also, when the two smallest diodes formed in accordance with the minimum design rule are compared, with the metal wirings 67 and 68 formed on one of them, the comparison result would indicate that the channel length was shortened by a distance corresponding to the minimum line widths of the metal wirings 67 and 68. This leads to a reduction in the light-receiving area.

The present invention was devised in consideration of the issues of the conventional technology discussed above. The present invention is aimed at: providing a photodiode that has minimum variation in the channel length that contributes to the photodiode properties in which the reduction in channel length is suppressed and the reduction in aperture ratio is minimized; providing a display device equipped with the aforementioned photodiode; providing a manufacturing method for the aforementioned photodiode; and providing a manufacturing method for a display device equipped with the aforementioned photodiode.

To solve the aforementioned issues, a photodiode according to the present invention is composed of a semiconductor film having a p-type semiconductor region, an i-type semiconductor region, and an n-type semiconductor region, which regions are sequentially formed on a substrate in a planar direction of the substrate, wherein the p-type semiconductor region and the n-type semiconductor region of the photodiode are connected to wiring films formed over an interlayer insulating film formed over the photodiode, via wirings provided through the interlayer insulating film, and the wiring films, which are formed over the interlayer insulating film, cover the p-type semiconductor region and the n-type semiconductor region, reach edges of an i-type semiconductor region, and determine a channel length contributing to properties of the photodiode.

According to this aspect, the wiring films are formed over the interlayer insulating film by etching with a high alignment precision. That is, since the photodiode channel length is determined by the wiring films formed by the high-precision etching, photodiodes having properties as designed, and multiple photodiodes having minimum variation in properties can easily be obtained. Also, the reduction in channel length can be suppressed, and the reduction in the aperture ratio can be minimized.

To solve the aforementioned issues, the display device equipped with the photodiode according to the present invention is a display device having a substrate on which active elements for display are formed and a photodiode formed on the substrate, wherein the photodiode is the photodiode according to claim 1.

According to this aspect, there is provided a display device equipped with a photodiode having superior properties that is formed on the same substrate with the active elements for display. This, in the case of a display device equipped with a number of photodiodes, suppresses the variation in photodiode properties.

To solve the aforementioned issues, in a display device equipped with another photodiode according to the present invention, the active elements are TFTs, and the wiring film formed over said interlayer insulating film is the same as a source wiring layer formed at the time of a TFT source wiring layer formation.

According to this aspect, the photodiode can be formed simultaneously with TFTs, which makes the manufacturing of the entire display device very simple.

To solve the aforementioned issues, in a display device equipped with another photodiode according to the present invention, the photodiode is for detecting ambient light and adjusts a display device luminance according to a brightness of the ambient light.

According to this aspect, upon detection of the ambient brightness of the site where the display device is used, the display device can display with a luminance corresponding to the ambient brightness. This feature allows optimum displays both indoors and outdoors, and also saves energy by avoiding higher than necessary display luminance.

To solve the aforementioned issues, in a display device equipped with another photodiode according to the present invention, the photodiode is disposed in the proximity of a pixel in a display region, and can be used for image capturing or for a touch panel.

According to this aspect, a plurality of photodiodes having consistent properties can be disposed in a display region that can be relatively large. This arrangement allows high-quality image capturing without any reading irregularities. A touch panel utilizing such photodiode can provide a high-quality, stable touch detection.

To solve the aforementioned issues, the fabrication method of the photodiode according to the present invention is a fabrication method for a photodiode made of a silicon film, having a p-type semiconductor region, an i-type semiconductor region, and an n-type semiconductor region, which regions are formed in a planar direction of a substrate, and is composed of the steps of: forming, on the substrate, the silicon film which is destined to become the photodiode; forming, on the silicon film, the p-type semiconductor region, the i-type semiconductor region, and the n-type semiconductor region to form the photodiode; forming an interlayer insulating film on the photodiode; and connecting the p-type semiconductor region and the n-type semiconductor region of the photodiode to the wiring film formed on the interlayer insulating film, wherein the wiring films are formed by etching, separately cover the p-type semiconductor region and the n-type semiconductor region, extend over edges of an i-type semiconductor region while sandwiching an interlayer insulating film inbetween, and determine a channel length of the photodiode.

According to this aspect, the wiring films can be formed over the interlayer insulating film by etching with a high alignment precision. That is, since the photodiode channel length is determined by the wiring films formed by the high-precision etching, photodiodes having properties as designed and multiple photodiodes having minimum variation in properties can easily be obtained. Also, the reduction in channel length can be suppressed, and the reduction in the aperture ratio can be minimized.

To solve the aforementioned issues, in the fabrication method for the display device equipped with the photodiode according to the present invention, active elements for display are fabricated simultaneously with the photodiode in the photodiode fabrication process.

According to this aspect, the photodiode can easily be formed simultaneously with active elements of display device, which makes the manufacturing of the entire display device very simple.

To solve the aforementioned issues, in the fabrication method for the photodiode-equipped display device of the present invention, the active elements are TFTs, and the wiring films are formed simultaneously with a source wiring layer for the active elements.

According to this aspect, photodiodes can easily be formed simultaneously with the TFTs of the display device, which makes the manufacturing of the entire display device very simple. Most fabrication processes for TFTs can be used for the photodiodes as well, eliminating the need for special processes for photodiodes. This helps keep the manufacturing cost of photodiode-equipped display devices low.

As described above, in an aspect of the present invention, the photodiode is made of a semiconductor film having a p-type semiconductor region, an i-type semiconductor region and an n-type semiconductor region, which regions are sequentially formed on a substrate in the planar direction of the substrate, wherein the p-type semiconductor region and the n-type semiconductor region of the photodiode are connected to wiring films formed over an interlayer insulating film formed over the photodiode, via the wirings provided through the interlayer insulating film; the wiring films formed over the interlayer insulating film cover the p-type semiconductor region and the n-type semiconductor region of the photodiode, reach the edges of i-type semiconductor region, and determine a channel length contributing to the photodiode properties.

Another aspect of the present invention is a fabrication method of the photodiode made of a silicon film having a p-type semiconductor region, an i-type semiconductor region, and an n-type semiconductor region, which regions are disposed in the planar direction of a substrate, and is composed of the steps of: forming, on the substrate, the silicon film which is destined to become the photodiode; forming, on the silicon film, the p-type semiconductor region, the i-type semiconductor region, and the n-type semiconductor region to form the photodiode; forming an interlayer insulating film on the photodiode; and connecting the p-type semiconductor region and the n-type semiconductor region of the photodiode to the wiring film formed on the interlayer insulating film, wherein the wiring films are formed by etching, separately cover the p-type semiconductor region and the n-type semiconductor region, extend over edges of an i-type semiconductor region while sandwiching an interlayer insulating film inbetween, and determine a channel length of the photodiode.

Accordingly, there provided is a photodiode that: has a channel width, which contributes to the photodiode properties, as designed; is capable of reducing the variations in the properties of photodiodes in the case that a number of photodiodes are formed; is capable of suppressing the channel length from being shortened; and is capable of minimizing the aperture ratio reduction. Also, a display device equipped with such photodiode, and the fabrication method of the same can be provided.

Other objects of the present invention, features, and distinguished attributes will be obvious from the description below. The advantages of the present invention will be clearly understood by the following description with reference to the figures attached.

### BRIEF DESCRIPTION OF THE DRAWINGS

FIG. 1 shows a structure of a photodiode fabricated according to an embodiment of the present invention.

FIG. 2 is a view that explains the first half of the photodiode fabrication process of the present invention.

FIG. 3 is a view that explains the latter half of the photodiode fabrication process of the present invention.

FIG. 4 shows an example of a display device equipped with photodiodes for an optical sensor.

FIG. 5 is a view that explains the structure of a conventional photodiode.

FIG. 6 is a view that explains the structure of a conventional photodiode.

### DETAILED DESCRIPTION OF EMBODIMENTS

Embodiments of the present invention are described below. The description below includes various limitations preferred for carrying out the present invention. However, the scope of the present invention is not limited to the embodiments and figures below.

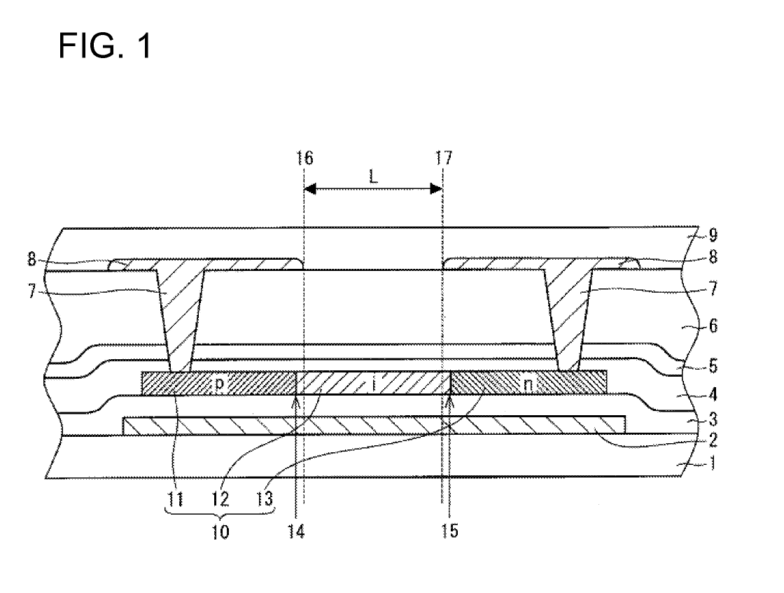

FIG. 1 is a view that shows the structure of a photodiode of the present invention, in which a cross section of the photodiode is illustrated. In FIG. 1, for simpler illustration of the photodiode of the present invention, some dimensions of components are shown enlarged than the actual dimensions, and the size of each component does not reflect the actual size.

In FIG. 1, “1” denotes a substrate made of a material such as glass. This substrate is identical to the substrate on which active elements such as TFTs (not shown) for driving the display device are disposed, and is also called an active matrix substrate. Base coat insulating film 3 is disposed on the substrate 1, and photodiode 10 is disposed on the base coat insulating film 3. The photodiode 10 is a lateral diode made of a semiconductor film having a p-type semiconductor region 11, an i-type semiconductor region 12, and an n-type semiconductor region 13, and these regions are sequentially formed in the planar direction of the substrate 1.

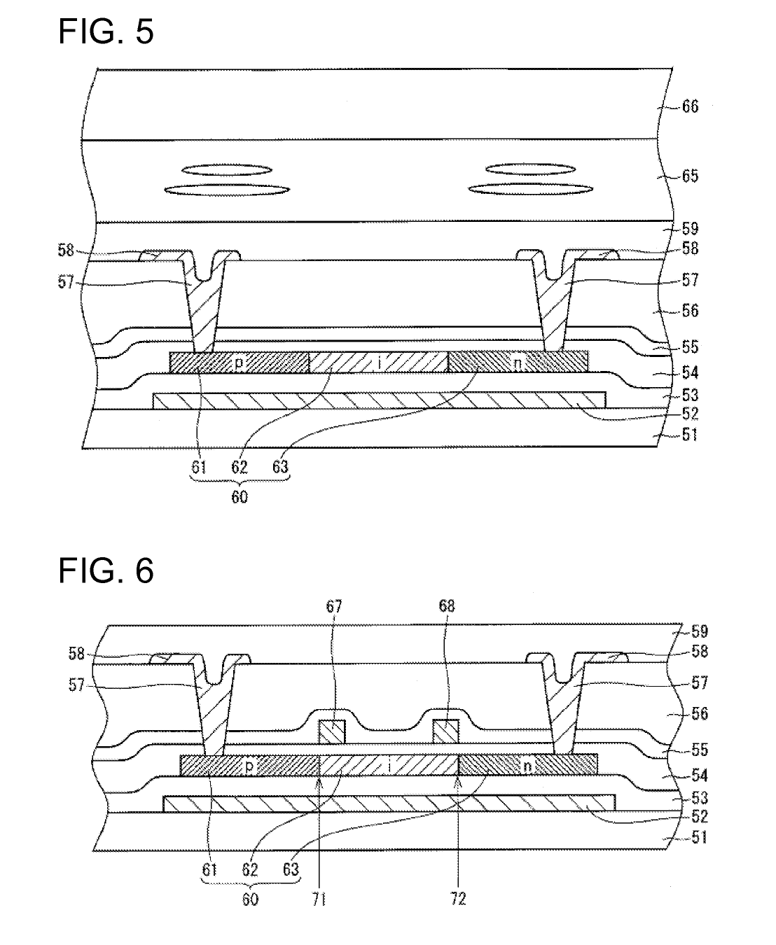

The p-type semiconductor region 11 and n-type semiconductor region 13 of the photodiode 10 are connected to source wiring films (wiring films) 8 via wirings 7 provided in the contact holes formed in a gate insulating film 4, an interlayer insulating film 5 and a planarizing layer 6. The source wiring film 8 serves as a lead-out electrode for driving the photodiode 10. As mentioned in the description of the conventional technology with reference to FIGS. 5 and 6, the gate insulating film 4 is identical to an insulating film formed simultaneously with the gate insulating layer in the formation process of active elements such as TFTs. The source wiring film 8 is so named due to the fact that it is a part of a wiring layer formed simultaneously with the source wiring layer and drain wiring layer for an active element such as a TFT, disregarding the fact that it is also the drain wiring formation part, for simplicity. A protective film 9 is provided on the source wiring film 8.

As shown in FIG. 1, the source wiring films 8 cover the p-type semiconductor region 11 and n-type semiconductor region 13 of the photodiode 10, slightly reaching over to the i-type semiconductor region 12. In FIG. 1, “14” denotes the border between the p-type semiconductor region 11 and i-type semiconductor region 12, and “15” denotes the border between the i-type semiconductor region 12 and n-type semiconductor region 13. In FIG. 1, “16” denotes the edge of the source wiring film 8 formed over the p-type semiconductor region 11, which, as obvious from FIG. 1, slightly extends into the i-type semiconductor region 12. Furthermore, in FIG. 1, “17” denotes the edge of the source wiring film 8 formed over the n-type semiconductor region 13, which, as obvious from FIG. 1, slightly extends into the i-type semiconductor region 12. In FIG. 1, the length “L”, the line segment between the edges 16 and 17 of the source wiring films 8, is the effective channel length, which is the dimension of the light receiving area of the photodiode 10.

The amount that the edges 16 and 17 of the source wiring films 8 extend into the i-type semiconductor region 12 depends on the alignment precision of photo etching. The smallest possible extending amount that is more than the alignment precision is preferred, which is, in practice, approximately 0.5 μm. The channel length “L” is approximately 5 μm.

As described later, the source wiring film 8 is formed by photo etching. The alignment precision of the photo etching is higher than the precision achievable by the mask formed by the resist pattern alone. As discussed above, the channel length “L” of the photodiode 10 depends on the precision of the source wiring film 8 formed by photo etching. Therefore, compared to the conventional technology shown in FIG. 5, photodiodes having less variable properties can be obtained.

As already described, the metal wirings 67 and 68 are disposed in the technology illustrated in FIG. 6, which results in a lower aperture ratio of the display. Furthermore, when the two smallest diodes formed in accordance with the minimum design rule, with the metal wirings 67 and 68 formed on one of them, are compared, the comparison result would indicate that the channel length is shortened by a distance corresponding to the minimum line widths of the metal wirings 67 and 68. This leads to problems such as a reduction in the light-receiving area. The photodiode 10 described earlier, on the other hand, has the source wiring film 8, which is an extension of wirings for driving the diode. Compared to the technology illustrated in FIG. 6, the loss in line width of the channel length “L” therefore is smaller.

The photodiode 10 can also be used for the ambient light detection of a display device, so that the display device brightness can be adjusted according to the ambient brightness. According to this, upon the detection of the ambient brightness of the site where the display device is used, the display device displays with a luminance corresponding to the ambient brightness. This feature allows for optimum displays both indoors and outdoors, and also saves energy by avoiding higher than necessary display luminance.

The photodiode 10 can also be disposed outside the display region of a display device. According to this, ambient light of the site where the display device is used can be detected outside but very close to the display region of the display device. As a result, the display device displays with a luminance corresponding to the ambient brightness. This feature allows for optimum displays both indoors and outdoors, and also saves energy by avoiding higher than necessary display luminance. In this case, the photodiode 10 does not have to be formed in the display region, which allows for a higher density of display elements in the display region and a higher aperture ratio of the display device.

The photodiode 10 can also be disposed in the display region of a display device, in proximity to each pixel. This arrangement can provide a display device equipped with photodiode 10 for image capturing or for touch detection for a touch panel. According to this, a plurality of photodiodes 10 having consistent properties allow for high-quality image capturing and allow for capturing without any reading irregularities. A touch panel utilizing such photodiode can provide a high-quality, stable detection of touch by, for example, fingers, and allows accurate tracing of complex touch movement.

Here, photodiode 10 may be formed in the proximity of each individual pixel, or one photodiode 10 may be formed for a plurality of pixels. Furthermore, a display device may be segmented, in which, for example, only display pixels are formed for the upper half of a display device, and one photodiode 10 is formed in the proximity of each display pixel for the lower half of the display device. Needless to say, also in this case, one photodiode 10 may be formed for a plurality of pixels.

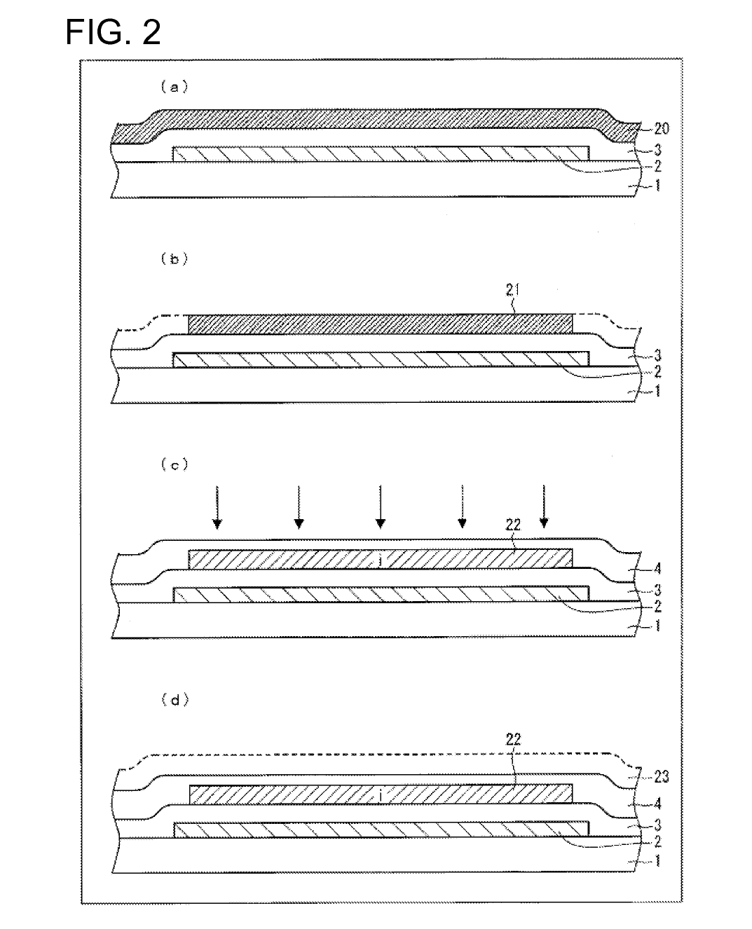

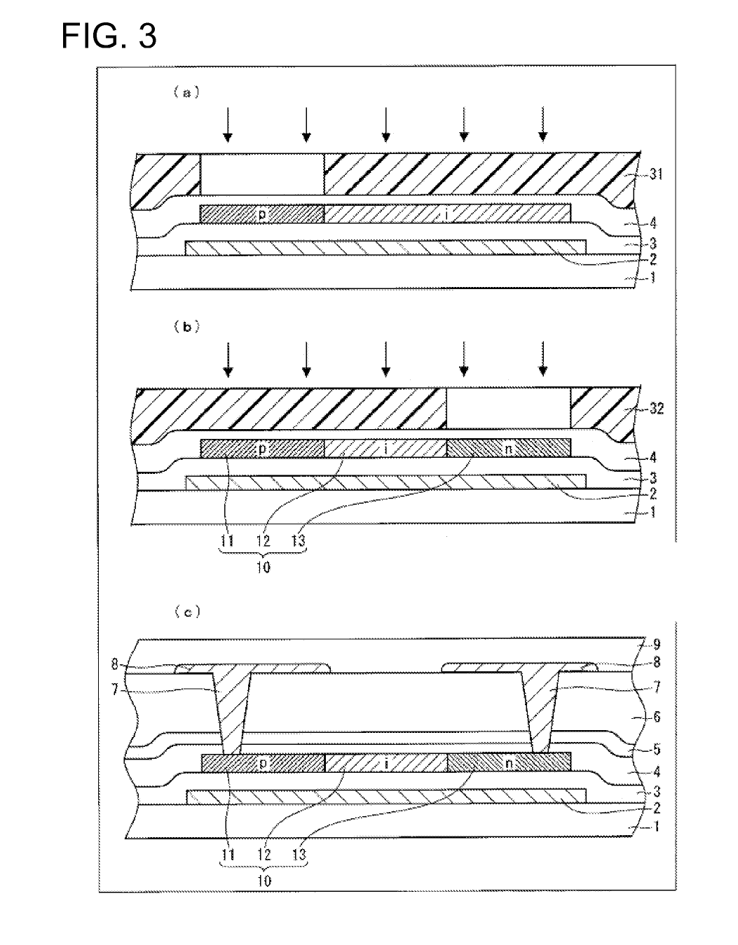

FIG. 2 and FIG. 3 show a fabrication method for the photodiode 10 of the present invention described with reference to FIG. 1. Although FIG. 2 and FIG. 3 only show the section in the proximity of the photodiode 10, a display device equipped with active elements such as TFTs can also be manufactured at the same time. Therefore, a manufacturing method for the display device equipped with photodiode 10 is also appropriately described. Here, in FIGS. 1, 2 and 3, the same reference characters are used for identical members. Redundant detailed explanations of identical members are omitted.

In FIG. 2 (a), “1” denotes a substrate made of a material such as glass. This is the identical to the glass substrate on which active elements such as TFTs are formed in the display region (not shown). Normally, a plurality of active elements are arranged in a matrix in the display region, and, therefore, this substrate is also called an active matrix substrate.

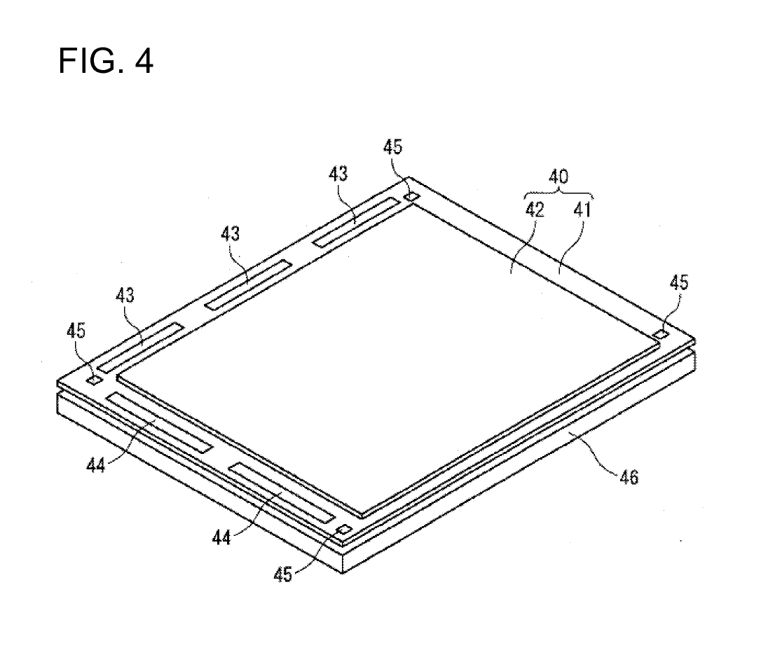

First, a light shielding film is deposited on one side of a glass substrate 1, which is a base member, by CVD (Chemical Vapor Deposition) or sputtering. The light shielding film may be made of an insulating material such as Si, or may be a metal film having main components such as tantalum (Ta), titanium (Ti), tungsten (W), molybdenum (Mo) and aluminum (Al). The film should have a thickness of, for example, 50 nm or more. Next, a resist pattern is developed by photolithography on the silicon film, of which the photodiode 10 will be formed, over the region that overlaps the light-shielding film formation region. Then, using the resist pattern as a mask, the insulating film or the metal film is etched to provide a light-shielding film 2. The light shielding film 2 is required when a backlight is disposed at the bottom as in FIG. 2, but not necessarily required for an application shown in FIG. 4.

Next, a base coat insulating film 3 is applied to cover the light shielding film 2. The base coat insulating film 3 can be deposited, for example, by CVD, in which a silicon oxide film or silicon nitride film is formed. The base coat insulating film 3 may be mono-layered or multi-layered. The thickness is set to, for example, 100 nm to 500 nm.

Then, silicon film 20, of which a photodiode will be made, is formed on the base coat insulating film 3 by CVD or other method. The silicon film 20 is formed of continuous grain crystal silicon or low temperature polysilicon. For example, a low temperature polysilicon film is formed in the following manner. First, silicon oxide film and amorphous silicon film are deposited sequentially over the base coat insulating film 3. Next, amorphous silicon film is laser-annealed to facilitate crystallization, to provide a silicon film 20 made of low temperature polysilicon.

In this embodiment, the silicon film 20 made of the low temperature polysilicon can also be used as a silicon film of which active element TFTs (not shown) are formed. In other words, the silicon film 20 can be deposited in the deposition process for the silicon film of which TFTs are formed.

Next, the silicon film 20 is patterned. FIG. 2 (b) shows this process. That is, a resist pattern is developed over the area that overlaps the photodiode formation region of the silicon film 20, and the silicon film 20 is etched using the resist pattern as a mask. This provides silicon film 21, a patterned silicon film, as shown in FIG. 2 (b).

Next, on the patterned silicon film 21, gate insulating film 4, which is going to be an interlayer insulating film, is formed. FIG. 2 (c) shows this process. The gate insulating film 4 is so named due to the fact that the gate insulating film 4 is deposited in the same deposition process for the gate insulating film of which TFTs are made. Similar to the base coat insulating film 3, the gate insulating film 4 may be a silicon oxide film or silicon nitride film formed by CVD or other methods, and may be mono-layered or a multi-layered. Specifically, a silicon oxide film can be formed by plasma CVD using SiH₄ and N₂O (or N₂O₂) gases. The thickness of the gate insulating film 4 is set to about 10 nm to 120 nm.

Next, to adjust the dosage of the patterned silicon film 21, a p-type impurity such as boron (B) and indium (In) are used for ion implantation at, for example, an implantation energy of 10 KeV to 80 KeV, and a dose of 5×10¹⁴ to 2×10¹⁶ ions. After the implantation, the impurity concentration is preferably 1.5×10²⁰ to 3×10²¹ ions per cm³. This provides silicon film 22 shown in FIG. 2 (c), patterned and dose adjusted.

Next, as shown in FIG. 2 (d), gate electrode film 23 is formed over the patterned and dose-adjusted silicon film 22. The gate electrode film 23 is etched into a predetermined shape in the TFT formation region to become a gate electrode. In the photodiode formation region, however, the gate electrode film 23 is removed when the gate electrode is formed by etching. FIG. 2 (d) shows this process, in which the gate electrode film 23 is denoted by a dashed line.

FIGS. 3 (a), (b), and (c) are views that explain the process in which the patterned and dose-adjusted silicon film 22 is subjected to the necessary ion implantation to form the p-type semiconductor region 11 and the n-type semiconductor 13, which semiconductor regions constitute a PiN photodiode 10.

FIG. 3 (a) is a view that explains the ion implantation process for a p-type diffusion layer. First, a resist pattern 31 is developed on the gate insulating film 4 by photolithography technology. The resist pattern 31 has an aperture over the area that eventually becomes the p-type semiconductor region 11 of the photodiode 10. Next, ion implantation is conducted using a p-type impurity such as boron (B) and indium (In) at, for example, an implantation energy of 10 KeV to 80 KeV, and a dose of 5×10¹⁴ to 2×10¹⁶ ions. After the implantation, the impurity concentration is preferably 1.5×10²⁰ to 3×10²¹ ions per cm³. After the ion implantation, the resist pattern 31 is removed.

Next, ion implantation to form an n-type diffusion layer is conducted. FIG. 3 (b) is a view that explains this process. FIG. 3 (b) shows only the photodiode formation area. However, in this embodiment, an n-type diffusion layer is formed simultaneously for the photodiode 10 for the sensor and for the TFT that is driving the pixels. Specifically, first, the resist pattern 32 is developed. The resist pattern 32 has apertures over the area that overlaps the n-layer formation region of the photodiode 10, and over the areas (not shown) that overlap the source region and drain region of the TFTs for driving the pixels. Next, ion implantation is conducted using an n-type impurity such as phosphorus (P) and arsenic (As) at, for example, an implantation energy of 10 KeV to 100 KeV, and a dose of 5×10¹⁴ to 1×10¹⁶ ions. After the implantation, the impurity concentration is preferably 1.5×10²⁰ to 3×10²¹ ions per cm³.

After the ion implantation, as shown in FIG. 3 (b), the photodiode 10 is formed, which has the p-type semiconductor region 11, i-type semiconductor region 12, and n-type semiconductor region 13. After the ion implantation, the resist pattern 32 is removed.

Next, as shown in FIG. 3 (c), an interlayer insulating film 5 and a planarizing layer 6 are formed. Then, contact holes are formed through the interlayer insulating film 5 and the planarizing layer 6, for connection to the electrodes from the p-type semiconductor region 11 and n-type semiconductor region 13. Wirings 7 are provided for the contact holes. Source wiring films 8 are formed by etching the source wiring layer formed on the photodiode 10 simultaneously with the source wiring layer in the TFT region. As explained earlier with reference to FIG. 1, the channel width “L” of the photodiode 10 can be precisely set by the source wiring films 8.

The display device equipped with photodiode 10 of the present invention may be, but not limited to, for example, a liquid crystal display device or an EL (Electro Luminescence) display device, and may be one of other types of display devices.

The display device may be, for example, a personal digital assistant (PDA) or a portable phone unit.

In figures in the description above, only the area in the proximity of the photodiode 10 is shown. However, it is apparent that the fabrication can be done simultaneously with TFTs as active elements in the display region, in the same formation process. It is also apparent that the photodiode 10 can be formed for each individual pixel.

The present invention is not limited to the embodiments described below. Those skilled in the art can modify the present invention within the scope defined by the appended claims. That is, a new embodiment may be obtained by combining the technological means that were modified as appropriate within the scope defined by the appended claims.

The specific embodiments or examples described in the detailed explanation of the present invention are merely for an illustration of the technical contents of the present invention. The present invention shall not be narrowly interpreted by being limited to such specific examples. Various changes can be made within the spirit of the present invention and the scope as defined by the appended claims.

### INDUSTRIAL APPLICABILITY

The present invention provides a display device equipped with a photodiode as an optical sensor, which photodiode may also be utilized for a touch panel. Display devices that the present invention may be applied to are not limited to liquid crystal display devices, but include various display devices such as EL display devices. Display devices equipped with such photodiodes are in use in a number of fields, which indicates a high industrial applicability of the present invention.

### DESCRIPTION OF REFERENCE CHARACTERS

1 substrate
2 light shielding film
3 base coat insulating film
4 gate insulating film
5 interlayer insulating film
6 planarizing layer
7 wiring
8 source wiring film (wiring film)
9 protective film
10 photodiode
11 p-type semiconductor region
12 i-type semiconductor region
13 n-type semiconductor region
14 border between p-type semiconductor region and i-type semiconductor region
15 border between i-type semiconductor region and n-type semiconductor region
16, 17 edge of the source wiring film
20 silicon film
21 patterned silicon film
22 patterned silicon film having an adjusted dose
23 gate electrode film
31, 32 resist pattern

1. A photodiode, composing
a semiconductor film having a p-type semiconductor region, an i-type semiconductor region, and an n-type semiconductor region, which regions are sequentially formed on a substrate in a planar direction of the substrate,
wherein said p-type semiconductor region and said n-type semiconductor region of said photodiode are connected to wiring films formed over an interlayer insulating film formed over said photodiode, via wirings provided through said interlayer insulating film, and
wherein said wiring films that are formed over said interlayer insulating film cover said p-type semiconductor region and said n-type semiconductor region, reach edges of an i-type semiconductor region, and determine a channel length contributing to properties of said photodiode.

2. A display device, comprising a substrate on which active elements for display are formed and a photodiode formed on said substrate, wherein said photodiode is the photodiode according to claim 1.

3. The photodiode-equipped display device according to claim 2, wherein said active elements are TFTs, and said wiring film formed over said interlayer insulating film is the same as a source wiring layer formed at the time of a TFT source wiring layer formation.

4. The photodiode-equipped display device according to claim 2, wherein said photodiode is for detecting ambient light and adjusts a display device luminance according to a brightness of the ambient light.

5. The photodiode-equipped display device according to claim 2, wherein said photodiode is disposed in the proximity of a pixel in a display region, and can be used for image capturing or for a touch panel.

6. The photodiode-equipped display device according to claim 2, wherein said photodiode-equipped display device is a liquid crystal display device or EL display device.

7. The photodiode-equipped liquid crystal display device according to claim 2, wherein said photodiode-equipped liquid crystal display device is a personal digital assistant or portable phone unit.

8. A fabrication method for a photodiode made of a silicon film having a p-type semiconductor region, an i-type semiconductor region, and an n-type semiconductor region, which regions are formed in a planar direction of a substrate, the method comprising the steps of:
forming, on said substrate, said silicon film which is destined to become said photodiode;
forming, on said silicon film, said p-type semiconductor region, said i-type semiconductor region, and said n-type semiconductor region to form said photodiode;
forming an interlayer insulating film on said photodiode; and
connecting said p-type semiconductor region and said n-type semiconductor region of said photodiode to said wiring film formed on said interlayer insulating film, wherein said wiring films are formed by etching, separately cover said p-type semiconductor region and said n-type semiconductor region, extend over edges of an i-type semiconductor region while sandwiching an interlayer insulating film inbetween, and determine a channel length of said photodiode.

9. The fabrication method for a photodiode-equipped display device, wherein active elements for display are fabricated simultaneously with the photodiode in the photodiode fabrication process according to claim 8.

10. The fabrication method for photodiode-equipped display device according to claim 9, wherein said active elements are TFTs, and said wiring films are formed simultaneously with a source wiring layer of said active elements.
